(19) United States
(12) Patent Application Publication
(10) Pub. No.: US 2012/0103651 A1
(43) Pub. Date: May 3, 2012

(54) HIGH-SPEED CABLE CONFIGURATIONS

(75) Inventor: Min Chul Kim, Santa Clara, CA (US)

(73) Assignee: Apple Inc., Cupertino, CA (US)

(21) Appl. No.: 13/033,553

(22) Filed: Feb. 23, 2011

Related U.S. Application Data
(60) Provisional application No. 61/408,052, filed on Oct. 29, 2010.

(51) Int. Cl. H05K 9/00; H01R 43/00

(52) U.S. Cl. 174/102 R; 29/825

(57) ABSTRACT

Cables that are capable of high-speed data transmission. One example provides a cable having conductors that have a low insertion loss. These cables may also be manufactured such that differential signals may be conveyed with minimal skew. The conductors may also be arranged in a manner that allows the cables to be bent and twisted with a reduced amount of damage.

### CROSS-REFERENCES TO RELATED APPLICATIONS

This application claims the benefit of U.S. provisional patent application No. 61/408,052, filed Oct. 29, 2010, titled High-Speed Cable Configurations, by Min Chul Kim, which is incorporated by reference.

### BACKGROUND

The amount of data transferred between electronic devices has grown tremendously the last several years. Large amounts of audio, streaming video, text, and other types of data content are now regularly transferred among desktop and portable computers, media devices, handheld media devices, displays, storage devices, and other types of electronic devices. Since it is often desirable to transfer this data rapidly, the data rates of these data transfers have substantially increased.

Transferring data at these rates has proven to require a new type of cable. Conventional cables are proving to have insufficient capabilities to handle signals at these higher data rates. New cables having improved capabilities are thus needed.

For example, conventional cables tend to have higher parasitic components, such as series resistance, than may be desirable. These parasitic components degrade signal levels and, along with other factors (such as reflections and parasitic capacitances), lead to higher insertion losses. These higher insertion losses may lead to reduced signal amplitude and corrupted signal edges, making accurate data reception more difficult.

Moreover, these high speed data signals are often differential signals. This requires two conductors in a cable. Any differences in the effective lengths of the two cables cause skews between the differential signals, further complicating data reception. These differences in effective length may result from non-optimized manufacturing procedures.

Also, since these cables are intended for external use (as opposed to being encased in a housing), they are often twisted and bent in various ways. These twists and bends may damage conventional cables.

Thus, what is needed are circuits, methods, and apparatus that provide cables capable of high-speed data transmission. It may be desirable that these cables have low insertion loss and are manufactured such that they have well-matched signal pairs. It may also be desirable that they be flexible so that they may be bent and twisted without damage.

### SUMMARY

Accordingly, embodiments of the present invention may provide cables capable of high-speed data transmission. A specific embodiment of the present invention may provide a cable having conductors that have a low insertion loss. These cables may also be manufactured such that differential signals may be conveyed with minimal skew. The conductors may also be arranged in a manner that allows the cables to be bent and twisted with a reduced amount of damage.

Specifically, an exemplary embodiment of the present invention may provide conductors that have a low insertion loss. These conductors may be formed from a number of strands or wires woven together. Each of these strands may be covered in enamel or other material to provide a physical separation in order to avoid an increase in resistance that may result due to skin effects. These strands may be woven in a manner that avoids electromagnetic dead zones that may occur with interior conductors. For example, the conductors may be woven in a manner consistent with a Litz wire.

The cables themselves may be manufactured in a manner that provides well-matched pairs of conductors that may be used to convey differential signals. For example, the cables may be formed of conductors, where the conductors are provided by spools. These spools may twist individually and as a group during manufacturing. The conductors may then be taped together and covered using an extrusion.

The conductors may be arranged in a manner that allows the cable to be bent and twisted with a reduced amount of resulting damage. For example, the conductors may be arranged as groups of twin-axial conductors. This may provide a cable arrangement that is symmetrical among multiple axes. The conductors may instead be arranged as a number of individual conductors in a manner that provides for a highly rounded cross section. In other embodiments of the present invention, the conductors may include one or more coaxial cables. In still other embodiments of the present invention, the conductors may include one or more shielded twisted pairs. These types of conductors may be combined with other types of conductors, fibers, and fillers. For example, fibers, such as aramid fibers, may be used to increase cable strength. Fillers, such as cotton or other material, may be used to provide a cable with a symmetrical rounded cross section. In other embodiments, asymmetrical cross sections may be utilized. In one embodiment of the present invention, an asymmetrical cross section is employed to provide cables having large diameter wires for conveying large amounts of current.

Various embodiments of the present invention may incorporate one or more of these and the other features described herein. A better understanding of the nature and advantages of the present invention may be gained by reference to the following detailed description and the accompanying drawings.

### BRIEF DESCRIPTION OF THE DRAWINGS

FIG. 1 illustrates a cross section of a conductor made up of a number of strands or wires;

FIG. 2 illustrates the construction of a cable according to an embodiment of the present invention;

FIG. 3 illustrates a twinaxial cable;

FIG. 4 illustrates an improved twinaxial cable;

FIG. 5 illustrates another improved twinaxial cable;

FIG. 6 illustrates various layers of a high-speed cable according to an embodiment of the present invention;

FIG. 7 illustrates a cross section of a high-speed cable according to an embodiment of the present invention;

FIG. 8 illustrates a cross section of another high-speed cable according to an embodiment of the present invention;

FIG. 9 illustrates a close-up view of a twinaxial cable that may be used as a center conductor in a high-speed cable according to an embodiment of the present invention;

FIG. 10 illustrates a cross section of a high-speed cable according to an embodiment of the present invention;

FIG. 11 illustrates a cross section of a high-speed cable according to an embodiment of the present invention;

FIG. 12 illustrates a cross section of a coaxial cable that may be used as a conductor according to an embodiment of the present invention;

FIG. 13 illustrates a cross section of another high-speed cable according to an embodiment of the present invention;

FIG. 14 is a more detailed view of another twisted pair according to an embodiment of the present invention;

FIG. 15 is a cross-section of a high-speed cable according to an embodiment of the present invention;

FIG. 16 illustrates a cross section of another high-speed cable according to an embodiment of the present invention; and

FIG. 17 illustrates a side view of a portion of the cable according to an embodiment of the present invention.

### DESCRIPTION OF ILLUSTRATIVE EMBODIMENTS

Active cables according to embodiments of the present invention may carry very high-speed signals. Unfortunately, conventional conductors or wires experience skin effects at high frequencies. The result of this is that high-frequency signals tend to propagate along the surfaces of the conductors. This reduces the effective cross section of a conductor and increases series resistance and therefore insertion losses, which degrade signal performance. This same effect holds true when a number of wires are bunched together as a group. That is, the signals tend to propagate along the outside of a number of wires that are in close proximity to each other, while center wires, and portions of outside wires near the center, carry little of the signal. Accordingly, embodiments of the present invention may provide for the separation of individual wires in a conductor. In various embodiments of the present invention, this separation may be achieved by coating each of the wires. This separation may increase the effective surface area and reduce signal degradation caused by skin effect. An example is shown in the following figure.

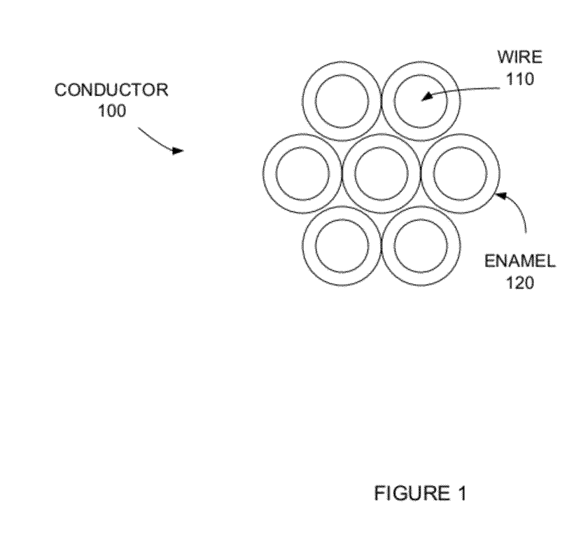

FIG. 1 illustrates a cross section of conductor 100 that may be made up of a number of strands or wires 110. This figure, as with the other included figures, is shown for illustrative purposes and does not limit either the possible embodiments of the present invention or the claims.

Each strand or wire 110 may be coated with a layer to provide separation among the wires 110. In this specific example, the coating may be formed of enamel 120. In other embodiments, other materials, such as plastic, may be used. This enamel layer 120 may separate wires 110. The separation may increase the effective cross section of conductor 100 at high frequencies. The increase in effective cross section may reduce series resistance, which in turn may reduce insertion losses.

Enamel layer 120 may also help to protect wires 110 from oxidation. Conventionally, silver plating may be used to reduce oxidation. But silver plating is expensive, as well as conductive. Since silver plating is conductive, it does not reduce the skin effect due to the proximity of wires 110 to each other.

In the configuration shown, if the center wire remains in the center of conductor 100 for the length of the cable, it tends to not convey the signal propagating through conductor 100. Accordingly, embodiments of the present invention may weave the inside wire to one of the outside wire positions, and one of the outside wires to an inside wire position, in an alternating fashion. This woven wire may be referred to as a Litz wire. This arrangement reduces losses caused by the center wires or wires being in an electromagnetic dead zone.

In this way, conductors according to an embodiment of the present invention may provide for a reduced skin effect, which reduces series resistance. These conductors may also provide enhanced conductivity for wires in a conductor by weaving inside wires to outside positions. By utilizing one or both of these features, embodiments of the present invention provide conductors having a reduced insertion loss. This may enable signal levels to be maintained and not lost to conductor parasitics. This in turn may allow cable lengths to be longer, since the signal strength is higher. It may also allow conductors, and therefore the cable, to be narrower, since series resistance is reduced.

While seven wires are show in this example, various embodiments of the present invention may provide conductors that include other numbers of wires. Conductors consistent with embodiments of the present invention may include more than seven wires, for example, a conductor may include nineteen, twenty-seven, or more wires. They may also include fewer than seven wires.

Wires 110 may be formed of copper, aluminum, or other material. They may be plated or coated with a layer of silver, tin, or other material. Again, while enamel layer 120 is shown in this example, in other embodiments of the present invention, other materials besides enamel may be used.

Enamel (or other material) layer 120 may electrically isolate wires 110 from each other. Accordingly, wires 110 may be connected together, for example, by soldering at one or both ends of the cable. In still other embodiments of the present invention, wires 110 may be connected at one or more points along the length of the cable.

Once the individual wires are made, several wires may be bound and covered in a jacket for protection to form a cable. One example of how this may be done is shown in the following figure.

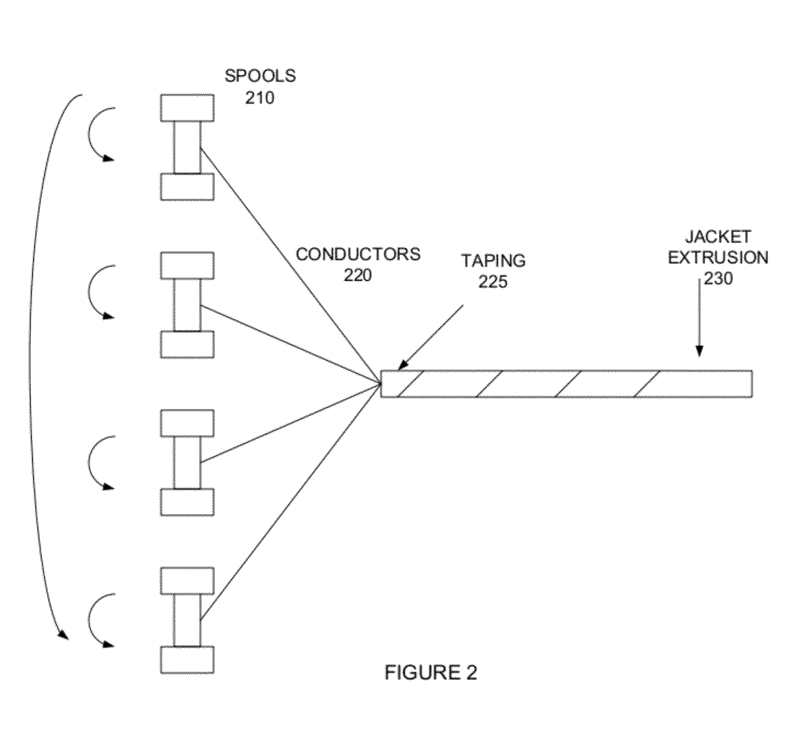

FIG. 2 illustrates the construction of a cable according to an embodiment of the present invention. In this example, a number of spools 210 may each hold one of the conductors 220. As the cable is formed, spools 210 may rotate, thereby individually twisting the wires. Also, spools 210 may twist as a group, thus twisting the wires as a group. For example, spools 210 may twist one-half turn, one turn, two turns, or other fractions or numbers of turns per length of cable. This combined twisting action may be referred to as planetary wire feeding, or as a planetary twist. In other embodiments of the present invention, other types of assembly may be used. For example, a back twist, or no twist, may be used. The various conductors may be bound together, for example using tape 225. A jacket may be extruded at 230, thus sealing the wires.

Spools 210 may hold various types of conductors or groups of conductors. For example, they may hold single conductors, coaxial cables, twisted pairs or shielded twisted pairs, or other types of conductors or groups of conductors. In a specific embodiment of the present invention, the conductors on one or more spools 210 are grouped in pairs, referred to as twinaxial, or twinax cables. Examples of twinaxial cables are shown in the following figures.

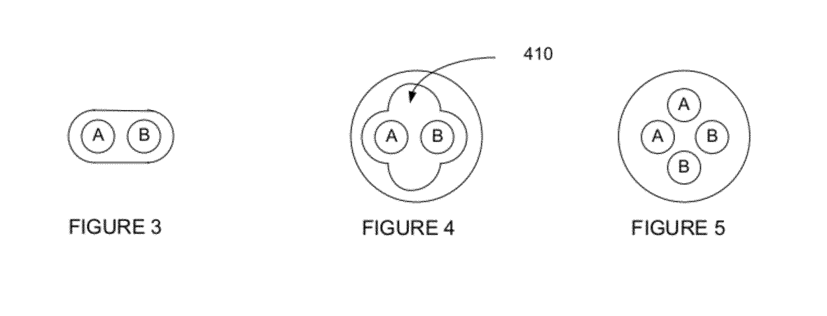

FIG. 3 to 5 illustrate twinaxial cables consistent with embodiments of the present invention. FIG. 3 illustrates a twinaxial cable having two wires. Unfortunately, this wire may bend differently as forces are applied in different directions. This can cause the cable to be damaged when bent or twisted. This can be improved by the structures shown in FIGS. 4 and 5. These cables may bend more symmetrically as forces are applied in various directions. For example, the use of a denser material 410 in FIG. 4 may make the cable bend similarly in horizontal and vertical directions. Splitting the two conductors A and B into four conductors in FIG. 5 may also make the cable bend similarly in horizontal and vertical directions.

Once the conductors have been grouped, various insulating and shielding layers may be placed over the conductors. An example is shown in the following figure.

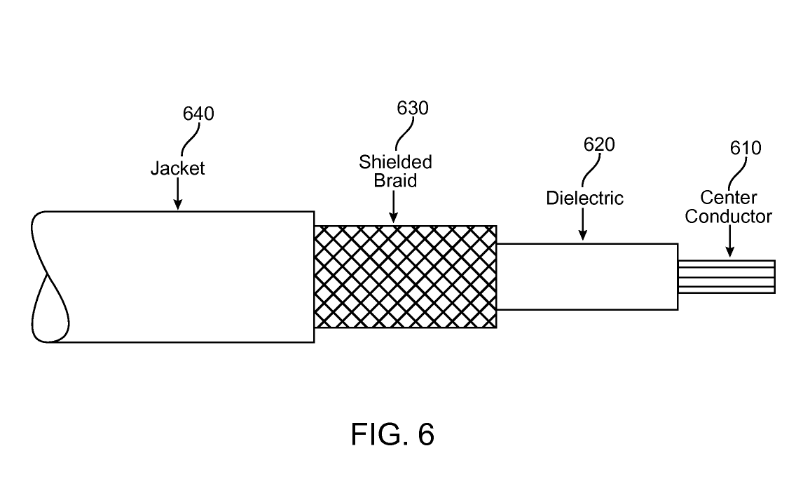

FIG. 6 illustrates various layers of a high-speed cable according to an embodiment of the present invention. This cable includes center conductors 610, dielectric 620, shielded braid 630, and jacket 640. Center conductors 610 may be formed using methods such as those outlined in FIG. 1. Center conductors 610 may include single conductors, coaxial conductors, or pairs of conductors, such as twinaxial, twisted-pair, shielded twisted pair, or other pairs of conductors.

Dielectric 620 may be included to isolate shielded braid 630 from center conductors 610. Dielectric 620 may reduce capacitance coupling effects between center conductors 610 and shielded braid 630. This reduced capacitance may improve performance and reduce insertion loss. Shielded braid 630 may provide a ground path through the cable. Shielded braid 630 may also provide electrical isolation (or RF shielding or isolation) for the center conductors 610. This isolation may protect the center conductors 610 from receiving noise and spurious signals, and the isolation may protect other lines or circuits from noise and spurious signals generated on the center conductors 610. Jacket 640 may be used to insulate shielded braid 630, to provide mechanical support, and to provide a tactile surface for users to manipulate.

Again, center conductors 610 may be formed of various conductors or groupings of conductors. Also, center conductors 610 may include fibers, filler, or other materials to increase strength and to provide a symmetrical cross section. Examples are shown in the following figures.

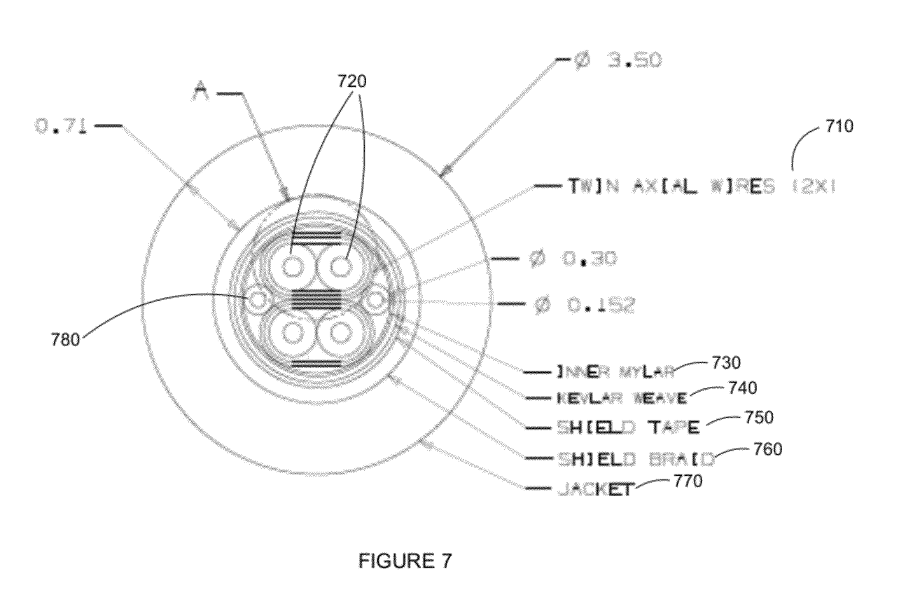

FIG. 7 illustrates a cross section of a high-speed cable according to an embodiment of the present invention. This cable includes two twinaxial pairs 710, as well as two other conductors 780. In one embodiment of the present invention, each twinaxial pair 710 may convey a differential signal. In other embodiments of the present invention, one or both of twinaxial pairs 710 may convey two separate signals. Conductors 780 may convey power, control signals, or other single-ended or differential data signals. In other embodiments of the present invention, conductors 780 may be replaced, or supplemented by, fiber, filler, or nonconductive strands. For example, fibers, such as aramid fibers, may be used to increase cable strength. Fillers, such as cotton or other material, may be used to provide a cable with a rounded cross section.

In this specific embodiment of the present invention, twinaxial cables 710 may be arranged one over the other, with conductors 780 on opposite sides. This may provide a symmetrical, rounded shape that is less likely to be damaged due to bending or twisting.

The center conductors, in this case twinaxial conductors 710 and conductors 780, may be surrounded by a Mylar™ layer 730. Mylar layer 730 may act to hold or bind the conductors 710 and 780 together during manufacturing. Mylar layer 730 may in turn be surrounded by a Kevlar™ layer 740 for mechanical stability. Shielded tape layer 750 and a shield braid layer 760 may be included. Again, this shielding may be used to provide RF isolation for the conductors 710 and 780. As before, jacket 770 may provide insulation as well as mechanical stability and a tactile surface for users.

In this and the other included examples, various layers are shown as being formed using a specific material. For example, in this figure, layer 730 is shown as being a Mylar layer, while layer 740 is shown as being a Kevlar layer. In various embodiments of the present invention, these and the other layers may be other materials. For example, the Mylar layers may be other versions or types of biaxially-oriented polyethylene terephthalate, while the Kevlar layers may be other versions or types of aramid material or fibers.

Also, in this example, two twinaxial cables 710 are included as inner conductors. In other embodiments of the present invention, other numbers of twinaxial cables may be included. An example is shown in the following figure.

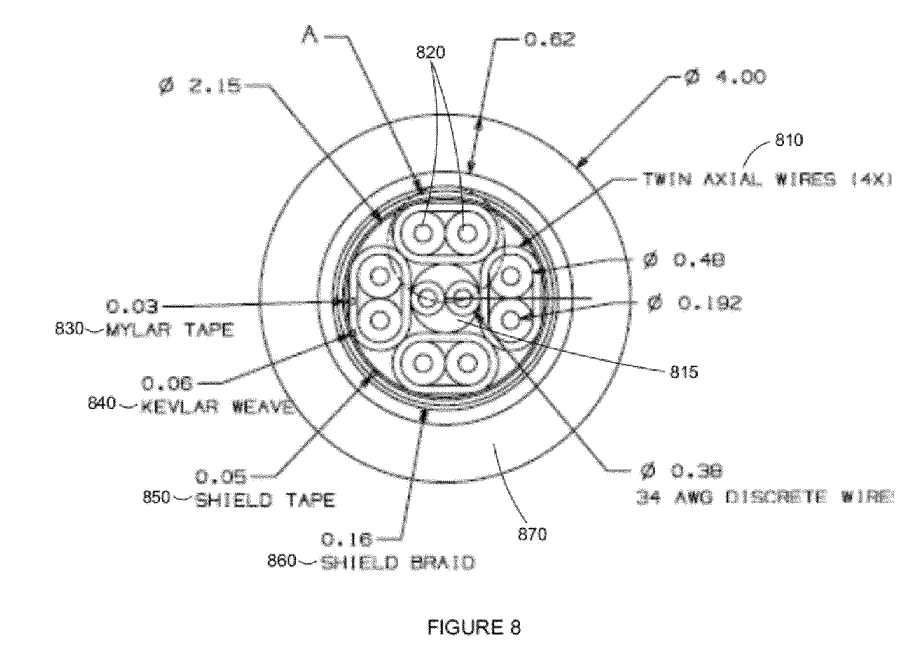

FIG. 8 illustrates a cross section of a high-speed cable according to an embodiment of the present invention. This high-speed cable may include four twinaxial cables 810 surrounding a pair of wires 815. In this example, each twinaxial cable 810 may be located above, below, to the right, or to the left of the pair of wires 815. As before, the center conductors may be surrounded by a layer of Mylar tape 830, a Kevlar layer 840, shielded tape 850, and shield braid 860. As before, a jacket 870 may be included for insulation and stability.

As before, this arrangement provides a highly symmetrical shaped cable that is less likely to be damaged during the bending or twisting that results from cable manipulation. Twinaxial cables 810 may be used to convey individual or differential signals. The center conductors may be used for status information, single-ended or differential data signals, or power. For example, center conductors 815 may be used to convey a differential signal, where skew between that differential signal and a differential signal conveyed by a twinaxial pair 810 is not critical.

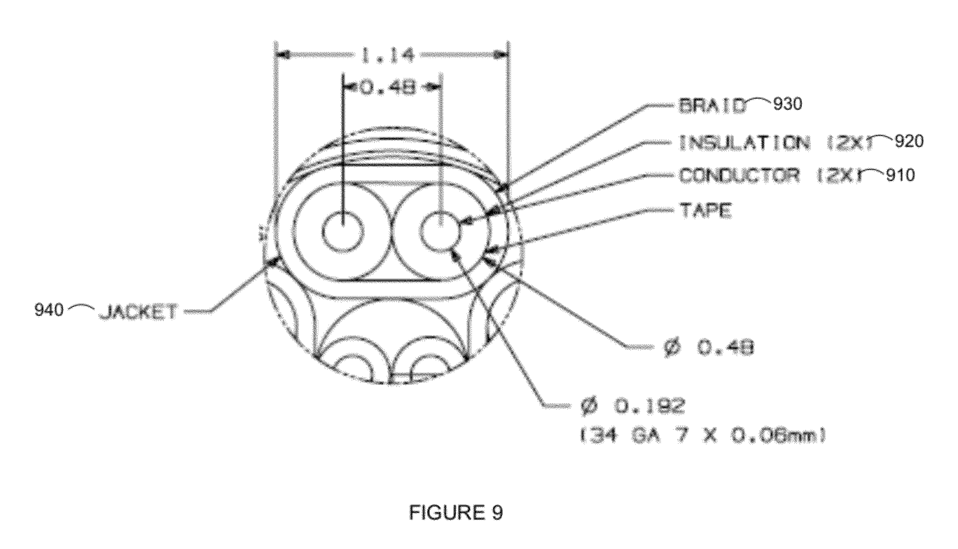

FIG. 9 illustrates a close-up view of a twinaxial cable that may be used as a center conductor in a high-speed cable according to an embodiment of the present invention. This twinaxial cable includes two conductors 910 surrounded by insulating layers 920. Braid layer 930 may also be included. As before, the braid layer 930 may be used to convey a ground signal and for shielding. Jacket 940 may surround braid layer 930 to provide mechanical support.

Twinaxial cables such as these provide two conductors that are well-suited for conveying high-speed differential signals. Again, any difference in effective length of either conductor results in skew between sides of a differential signal. Since both conductors in a twinaxial cable stay together as the overall cable bends, twinaxial cables tend to provide conductors having well-matched effective lengths.

Again, in other embodiments of the present invention, the center conductors may be individual conductors. An example is shown in the following figure.

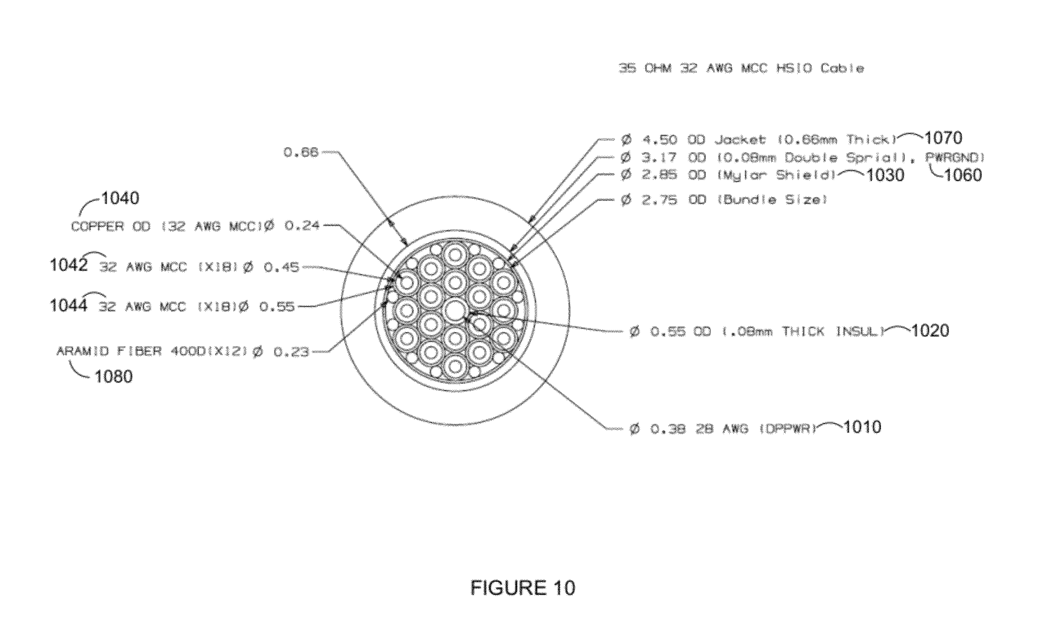

FIG. 10 illustrates a cross section of a high-speed cable according to an embodiment of the present invention. This figure includes a center conductor 1010 surrounded by a number of second conductors 1040. Non-conductive fibers or other conductors 1080 may be used such that the center conductors are arranged in a symmetric or substantially rounded shape. As before, this arrangement provides a cable that is less prone to damage due to twisting or bending that may result during cable use.

Again, this cable includes a center conductor 1010. Center connector 1010 may be used to convey power or other status or data signals. Insulating layer 1020 may surround conductor 1010. A number of second conductors 1040 are also included. These may convey single ended, differential, status, control, or other types of data signals or power. Insulating layers 1042 and 1044 may be included around each conductor. Mylar shield 1030 may surround the center conductors to bind the conductors together. As before, braiding 1060 and jacket 1070 may also be included, for RF shielding, mechanical support, and other reasons.

Again, in other embodiments of the present invention, one or more of the conductors may be a coaxial cable. An example is shown in the following figure.

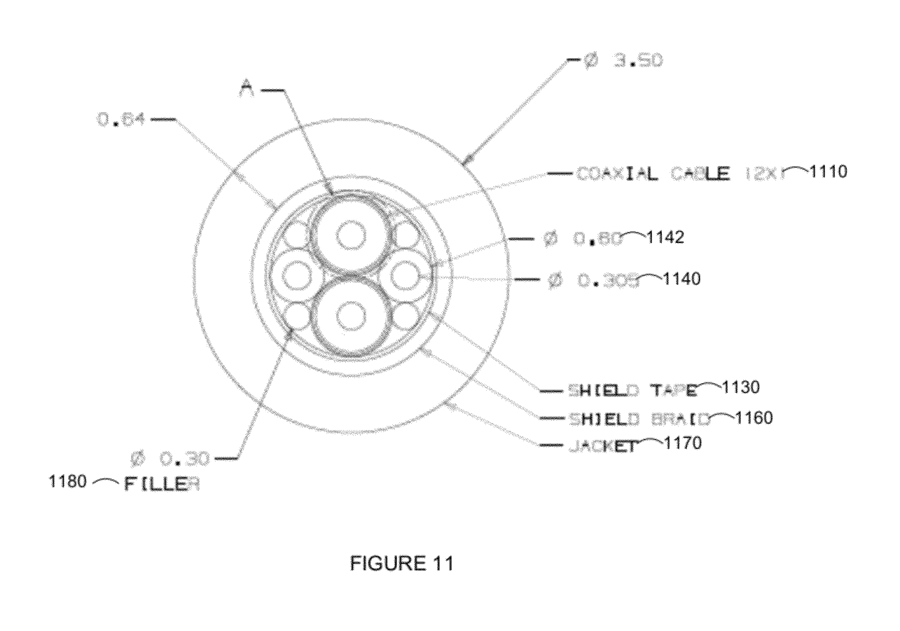

FIG. 11 illustrates a high-speed cable according to an embodiment of the present invention. This figure includes two coaxial cables 1110 as well as two other conductors 1140. Coaxial cables 1110 may be used to convey single-ended or differential signals. Conductors 1140 may be used to convey data, status, control, or other types of data signals or power. Filler 1180 may be used to provide a rounded cross section for the high-speed cable, such that the high-speed cable is less likely to be damaged by bending or twisting during cable usage. As before, the center conductors may be surrounded by shield tape 1130, shield braid layer 1160, and jacket 1170.

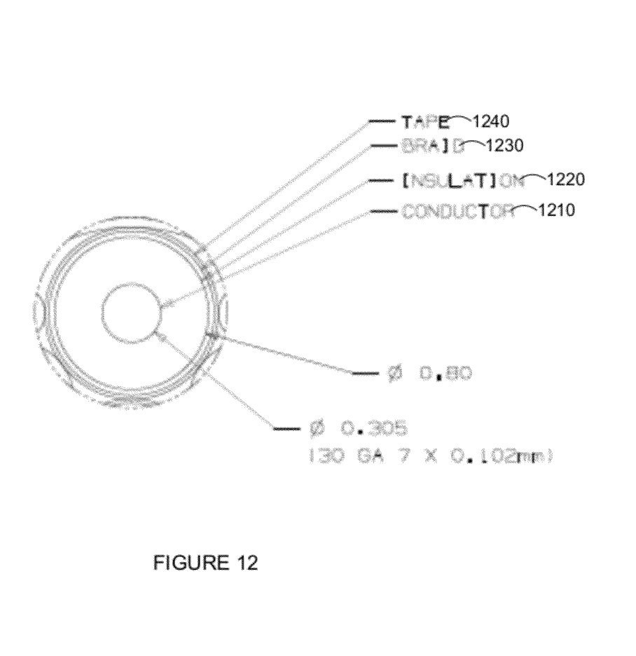

FIG. 12 illustrates a cross section of a coaxial cable that may be used as a conductor according to an embodiment of the present invention. In this example, conductor 1210 may be surrounded by insulation layer 1220. Braid layer 1230 may surround insulation layer 1220. Braid layer 1230 may be used to convey ground signal and provide RF isolation. Tape layer 1240 may surround braid layer 1230 and be used to provide mechanical stability to the coaxial cable.

While several of the specific embodiments of the present invention illustrated here provide a symmetrical cross-section, other embodiments of the present invention provide cables having asymmetric cross-sections, or cross sections that are only symmetrical in along one or more axes. An example is shown in the following figure.

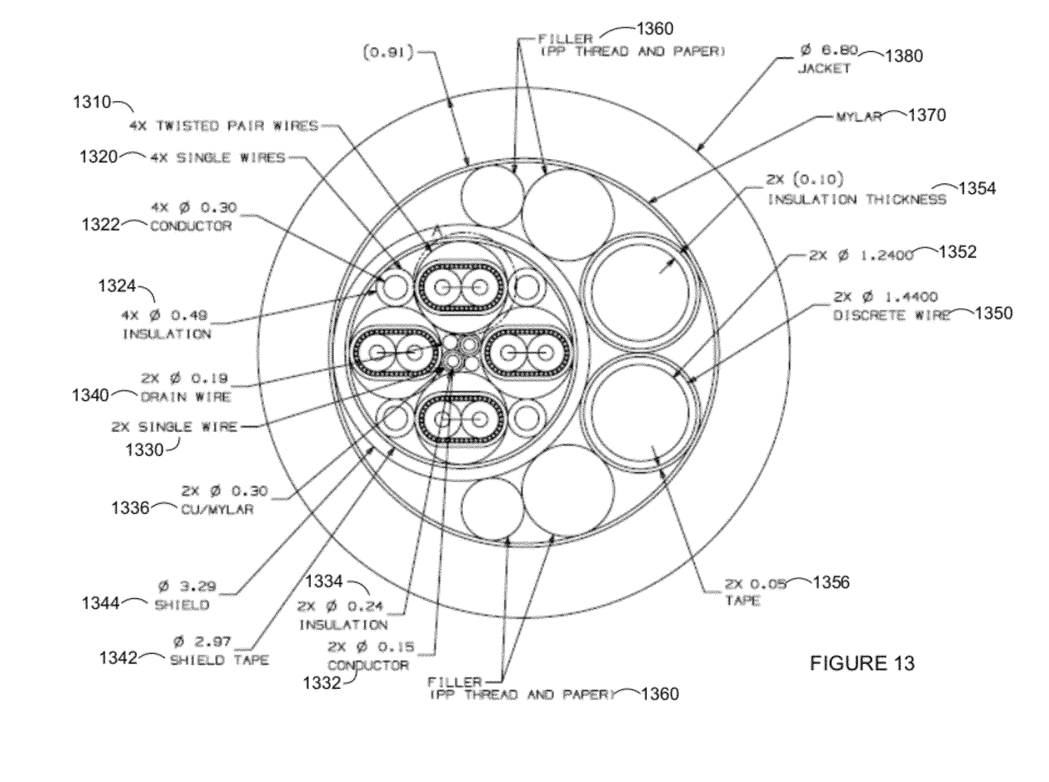

FIG. 13 illustrates a cross section of another high-speed cable according to an embodiment of the present invention. In this embodiment of the present invention, the use of an asymmetric arrangement allows for the inclusion of wires having a relatively large diameter. These large diameter wires are particularly useful in carrying voltage supplies and high power systems. In this embodiment of the present invention, two wires 1350 are included. These wires are formed of a connector 1352 surrounded by insulators 1354. This cable configuration also includes four twisted pairs 1310, and four wires 1320. Twisted pairs 1310 further surround two wires 1330 and two drain wires 1340.

Wires 1320 may be formed of conductors 1322, which are surrounded by insulators 1324. Twisted pair wires 1310, and wires 1320, 1330, and 1340, may be bound together with shield tape 1342, and surrounded by shield layer 1344. Filler or other fibers 1360 may be used to complete the cable.

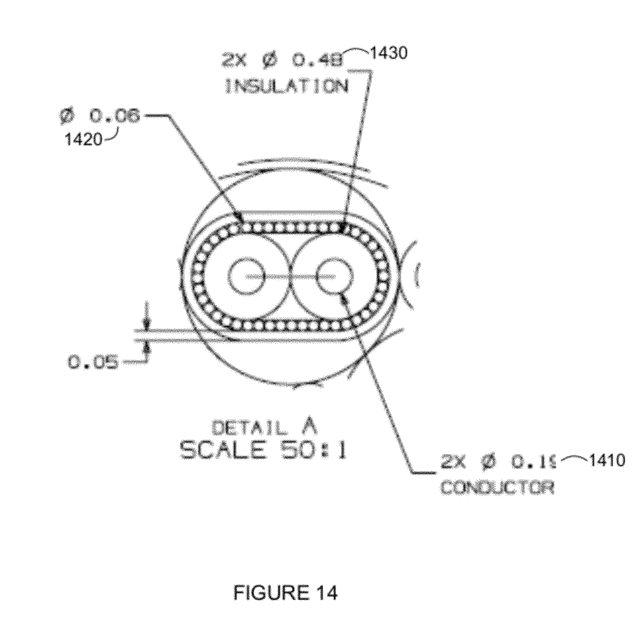

FIG. 14 is a more detailed view of twisted pair 520 according to an embodiment of the present invention. Twisted pairs 520 may include two conductors 610 surrounded by insulation layer 630. Spiral shield 620 may surround twisted-pair 520 and provides shielding against electromagnetic interference. Spiral shield 620, like shield braid 540, may be formed of braiding, one or more counter-rotating spirals, or other ways. Copper Mylar tape layer 670 may bind and provide mechanical support for spiral shield 620 and conductors 610.

Again, embodiments of the present invention may provide a cable having a high strength. To provide this increased strength, a shield or braiding surrounding the cable or one or more of its conductors may include one or more types of fibers. For example, aramid fibers may be included in a shield or braiding around the cable. Unfortunately, aramid fibers may interfere with soldering, for example when the shield is to be soldered to a connector frame or pad. To simplify soldering of the braiding, the aramid or other fibers may be bunched or grouped in the cable shield or braiding, such that they may be pulled out of the way during soldering. In various embodiments of the present invention, these fibers may be pulled out of the way using static electricity, or by other mechanisms. An example of such a cable is shown in the following figure.

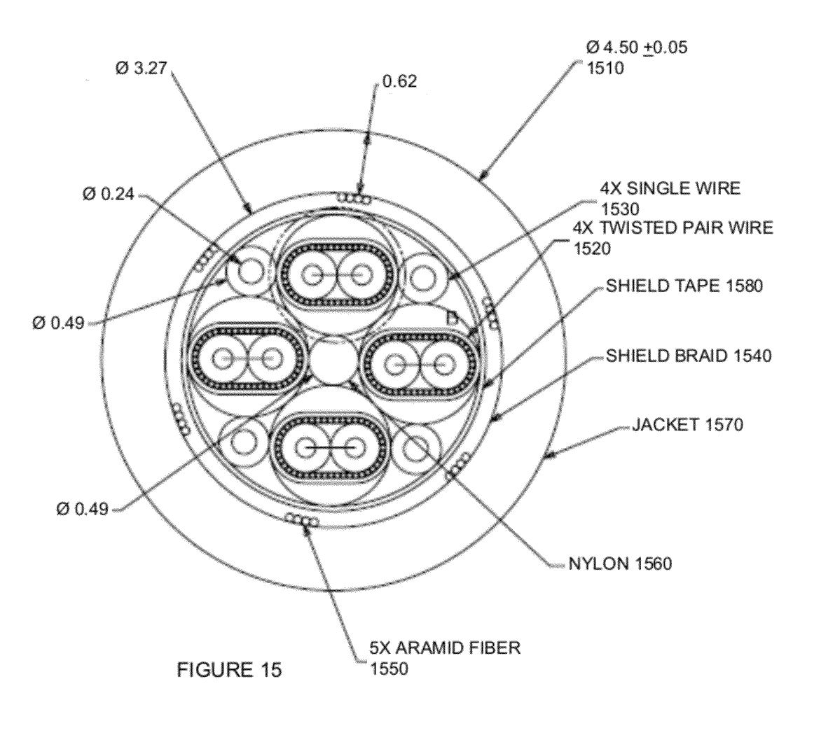

FIG. 15 is a cross-section of a high-speed cable according to an embodiment of the present invention. This cable may include four twisted pairs 1520 and four single wires 1530. Twisted pairs 1520 may be used to carry differential signals, multiple single ended signals, power, ground, bias, control, status, or other types of signal, power, status, or control lines. Single wires 1530 may be used to convey single ended signals, one side of a differential signal, power, ground, bias control, status, or other types of signal, power, status, or control lines. In other embodiments the present invention, cables consistent with embodiments of the present invention may include other numbers of twisted pairs and single wires.

In this example, twisted-pairs 1520 and single wires 1530 surround a nylon core 1560, which is used for mechanical support. In other embodiments of the present invention, nylon core 1560 may be substituted by a wire, one or more fiber-optic lines, or other conductor or fiber. These connectors may be bound by shield tape 1580.

Shield braid 1540 may surround the cable. Jacket 1570 may surround shield braid 1540 and provide mechanical support for the cable. Again, aramid fibers 1550 may be dispersed or grouped in shield braid 1540. Shield braid 1540 may be a conventional interwoven braiding, shield braid 1540 may be formed of one or more counter-rotating spirals, or shield braiding 1540 may be formed in other various ways.

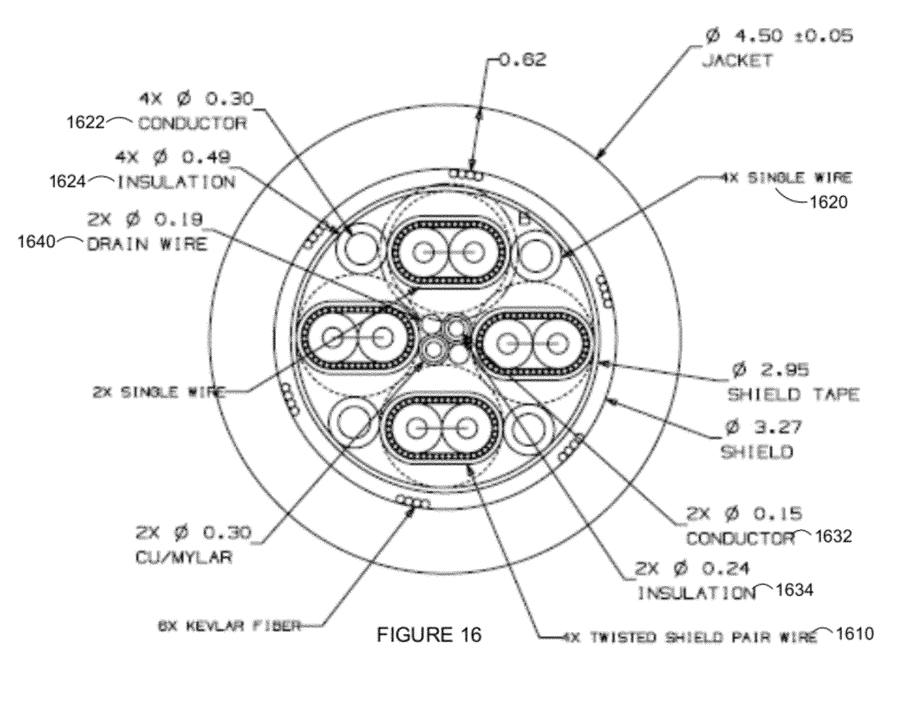

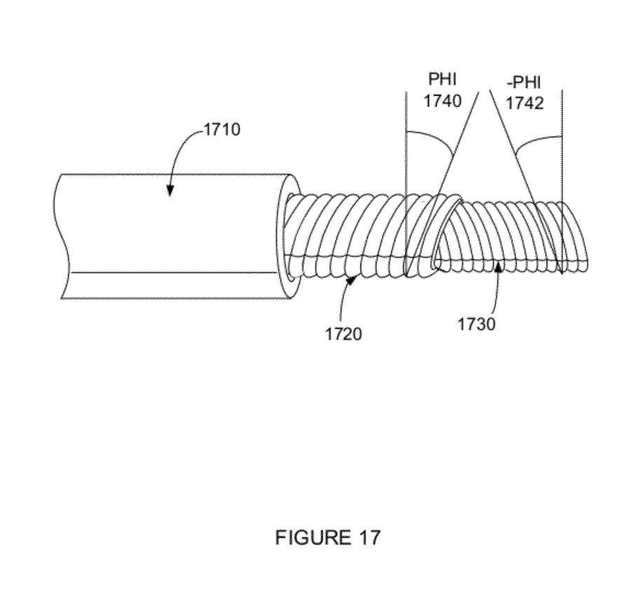

FIG. 16 illustrates a cross section of another high-speed cable according to an embodiment of the present invention. This cable may be similar to the cable illustrated in FIG. 15. In this example, nylon core 1560 may be replaced by one or more wires. Specifically, this cable may include four twisted pair wires 1610, and four single wires 1620. Twisted pairs 1610 may surround two conductors 1632 and two drain wires 1640.

In the above examples, a shield layer may be included. In these examples, the shield may be braided. In these and other embodiments of the present invention, the shield may be formed of layers of wire arranged in counter-rotating spirals. Specifically, the shield may be formed of layers of wires, where the wires in each layer are roughly in parallel with each other. These wires may wrap in a rotating manner along the length of a cable at an angle. In a specific embodiment of the present invention, the angle is approximately seventeen degrees, though in other embodiments of the present invention, other angles may be used. Shields formed in this manner may include one, two, or more than two layers of wires. For example, a shield may include two layers of wires wrapped in counter-rotating spirals. An embodiment is shown in the following figure.

FIG. 17 illustrates a side view of a portion of the cable according to an embodiment of the present invention. This figure illustrates a cable surrounded by jacket 1710. Jacket 1710 has been cut away to reveal a first counter-rotating spiral 1720 and a second counter-rotating spiral 1730. The first of these spirals may have an angle approximately equal to phi 1740. In a specific embodiment of the present invention, phi may be equal to 17 degrees. In other embodiments of the present invention, other angles may be used. The second of these may have approximately the same relative angle, shown here as negative phi 1742 to indicate a different absolute direction.

In this way, during manufacturing, the wires in the counter-rotating spirals 1720 and 1730 may be easily peeled away, straightened, and soldered or otherwise electrically connected to locations in a connector plug.

Utilizing counter-rotating spirals 1720 and 1730 may also improve flexibility of the cable. For example, when the cable is twisted in a first direction, counter-rotating spiral 1720 may tighten while counter-rotating spiral 1730 may loosen. The tightening of counter-rotating spiral 1720 may protect the internal conductors. Similarly, when the cable is twisted in a second direction, counter-rotating spiral 1730 may tighten while counter-rotating spiral 1720 may loosen. The tightening of counter-rotating spirals 1730 may protect the internal conductors.

Again, one or more different types of fibers may be employed by embodiments of the present invention. These fibers may be interspersed singly or in groups in one or more of the counter-rotating spirals 1720 and 1730. These fibers may be included for various reasons.

In a specific embodiment of the present invention, aramid fibers may be included for additional strength. Again, aramid fibers may interfere with soldering of the counter-rotating spirals 1720 and 1730 to locations such as a shield of, or pads in, a connector insert. Accordingly, in various embodiments of the present invention, these fibers may be pulled away from the wires in the counter-rotating spirals 1720 and 1730 by static electricity, air movement, or other methods.

The above description of embodiments of the invention has been presented for the purposes of illustration and description. It is not intended to be exhaustive or to limit the invention to the precise form described, and many modifications and variations are possible in light of the teaching above. The embodiments were chosen and described in order to best explain the principles of the invention and its practical applications to thereby enable others skilled in the art to best utilize the invention in various embodiments and with various modifications as are suited to the particular use contemplated. Thus, it will be appreciated that the invention is intended to cover all modifications and equivalents within the scope of the following claims.

What is claimed is:

1. A high-speed cable comprising:
a plurality of conductors, at least one of the plurality of conductors comprising a first plurality of wires, and
a shield comprising a second plurality of wires arranged in a plurality of counter-rotating spirals,
wherein the plurality of wires are electrically connected, and
wherein each wire has a coating such that the plurality of wires are substantially electrically separate from each other along the length of the cable.

2. The high-speed cable of claim 1 wherein the coating is enamel.

3. The high-speed cable of claim 2 wherein the first plurality of wires are arranged such that no wire in the plurality of wires is in the center of the plurality of wires for a substantial length of the cable.

4. The high-speed cable of claim 2 wherein the first plurality of wires are arranged as a Litz wire.

5. The high-speed cable of claim 1 wherein the first plurality of wires are copper.

6. The high-speed cable of claim 5 wherein the first plurality of wires are substantially free of a silver coating.

7. The high-speed cable of claim 2 wherein at least two of the conductors are arranged as a twinaxial cable.

8. The high-speed cable of claim 2 wherein the plurality of conductors are arranged in a roughly circular manner.

9. The high-speed cable of claim 2 wherein the cable further comprises a least one filler strand, and
wherein the filler strand and the plurality of conductors are arranged in a roughly circular manner.

10. The high-speed cable of claim 2 wherein at least one of the conductors is arranged as a coaxial cable.

11. A method of manufacturing a high-speed cable comprising:
coating a first plurality of wires with a first coating;
weaving the first plurality of wires to form a first conductor such that any wire in the plurality of wires is not in a center of the plurality of wires for a substantial length of the cable; and
forming a shield of a second plurality of wires arranged in a plurality of counter-rotating spirals.

12. The method of claim 11 wherein the first coating is enamel.

13. The method of claim 11 further comprising:
twisting each of the first conductor and a plurality of second conductors to form a plurality of conductors; and
coating the plurality of conductors with a second coating.

14. The method of claim 13 further comprising:
twisting the plurality of conductors.

15. The method of claim 14 wherein the plurality of conductors are twisted once per length of cable.

16. The method of claim 14 wherein the plurality of conductors are twisted one half turn per length of cable.

17. The method of claim 11 further comprising:
arranging the first conductor with a second conductor as a twinaxial cable.

18. The method of claim 11 further comprising:
arranging the first conductor with a plurality of other conductors in a substantially circular manner.

19. The method of claim 11 further comprising:
electrically connecting the first plurality of wires of the first conductor.

20. A high-speed cable comprising:
a first plurality of conductors arranged as a plurality of twinaxial cables; and
a second plurality of conductors;
wherein the first plurality of conductors and the second plurality of conductors are arranged in a roughly circular manner.

21. The high-speed cable of claim 20 wherein a first conductor in the first plurality of conductors comprises a plurality of wires, wherein the plurality of wires are electrically connected, and wherein each wire has a coating such that the plurality of wires are substantially electrically separate from each other along the length of the cable.

22. The high-speed cable of claim 21 wherein the coating is enamel.

23. A high-speed cable comprising:
a first plurality of conductors arranged as a plurality of coaxial cables;
a second plurality of conductors;
wherein the first plurality of conductors and the second plurality of conductors are arranged in a roughly circular manner.

24. The high-speed cable of claim 23 wherein a first conductor in the first plurality of conductors comprises a plurality of wires, wherein the plurality of wires are electrically connected, and wherein each wire has a coating such that the plurality of wires are substantially electrically separate from each other along the length of the cable.

25. The high-speed cable of claim 24 wherein the coating is enamel.
